(19) United States
(12) Patent Application Publication
(10) Pub. No.: US 2015/0076980 A1
(43) Pub. Date: Mar. 19, 2015

(54) FASTENER ASSEMBLY FOR A DOOR

(71) Applicant: Caterpillar Inc., Peoria, IL (US)

(72) Inventors: Andrew B. Robinson, Centralia, IL (US); Michael J. Jensen, Peoria, IL (US); Jeffrey J. Johnson, Bolingbrook, IL (US)

(73) Assignee: Caterpillar Inc., Peoria, IL (US)

(21) Appl. No.: 14/031,064

(22) Filed: Sep. 19, 2013

(51) Int. Cl. H05K 5/02; E05C 19/00

(52) U.S. Cl. CPC H05K 5/0221; E05C 19/00; H05K 5/0239
USPC 312/293.3; 292/301

(57) ABSTRACT

A fastener assembly arranged about a perimeter of a door for an enclosure is provided. The fastener assembly includes a compression limiter, a bolt and a retaining ring. The compression limiter is disposed on an inner surface of the door and configured to press against a fastener receptacle block on the enclosure. The compression limiter has an opening. The bolt passes through the opening of the compression limiter and is configured to be fastened to a threaded opening in the fastener receptacle block. The retaining ring is disposed in the opening of the compression limiter and is configured to retain the bolt with the door.

### TECHNICAL FIELD

The present disclosure relates to a door for an enclosure, and more particularly to a fastener assembly for fastening the door to the enclosure.

### BACKGROUND

Cabinets, such as inverter cabinets include doors that can be detached from an enclosure of the cabinet. The doors are generally fastened and/or sealed to a frame of the enclosure using fasteners and have gasket seals. Fastening the doors to the enclosure may require a manual force to be applied on the door against the enclosure. However, applying too much force on the door may damage the fasteners and/or the gasket seals. Additionally, while fastening and/or unfastening the door from the enclosure, the fasteners tend to fall out of the door, which may not be desired as per safety regulations. Also, according to various safety requirements, it may be important to ground the doors to the enclosure.

### SUMMARY OF THE DISCLOSURE

In one aspect of the present disclosure, a fastener assembly arranged about a perimeter of a door for an enclosure is provided. The fastener assembly includes a compression limiter, a bolt and a retaining ring. The compression limiter is disposed on an inner surface of the door and configured to press against a fastener receptacle block on the enclosure. The compression limiter has an opening. The bolt passes through the opening of the compression limiter and is configured to be fastened to a threaded opening in the fastener receptacle block. The retaining ring is disposed in the opening of the compression limiter and is configured to retain the bolt with the door.

In another aspect of the present disclosure, a door for an enclosure is provided. The door includes a panel configured to cover an entrance of the enclosure. Further, the door includes a fastener assembly arranged about a perimeter of a door for an enclosure is provided. The fastener assembly includes a compression limiter, a bolt and a retaining ring. The compression limiter is disposed on an inner surface of the door and configured to press against a fastener receptacle block on the enclosure. The compression limiter has an opening. The bolt passes through the opening of the compression limiter and is configured to be fastened to a threaded opening in the fastener receptacle block. The retaining ring is disposed in the opening of the compression limiter and is configured to retain the bolt with the door.

In a yet another aspect, an inverter cabinet including an enclosure is provided. The enclosure includes a housing and an entrance to the housing. The enclosure further includes a fastener receptacle block arranged about a perimeter of the entrance and the fastener receptacle block has a threaded opening. Furthermore, the inverter cabinet includes a door for an enclosure is provided. The door includes a panel configured to cover an entrance of the enclosure. Further, the door includes a fastener assembly arranged about a perimeter of a door for an enclosure is provided. The fastener assembly includes a compression limiter, a bolt and a retaining ring. The compression limiter is disposed on an inner surface of the door and configured to press against a fastener receptacle block on the enclosure. The compression limiter has an opening. The bolt passes through the opening of the compression limiter and is configured to be fastened to a threaded opening in the fastener receptacle block. The retaining ring is disposed in the opening of the compression limiter and is configured to retain the bolt with the door.

Other features and aspects of this disclosure will be apparent from the following description and the accompanying drawings.

### BRIEF DESCRIPTION OF THE DRAWINGS

FIG. 1 illustrates an exemplary cabinet, according to an embodiment of the present disclosure;

FIG. 2 illustrates a perspective view of a fastener assembly for the cabinet; and

FIG. 3 illustrates another view of the fastener assembly according to the embodiment of this disclosure.

### DETAILED DESCRIPTION

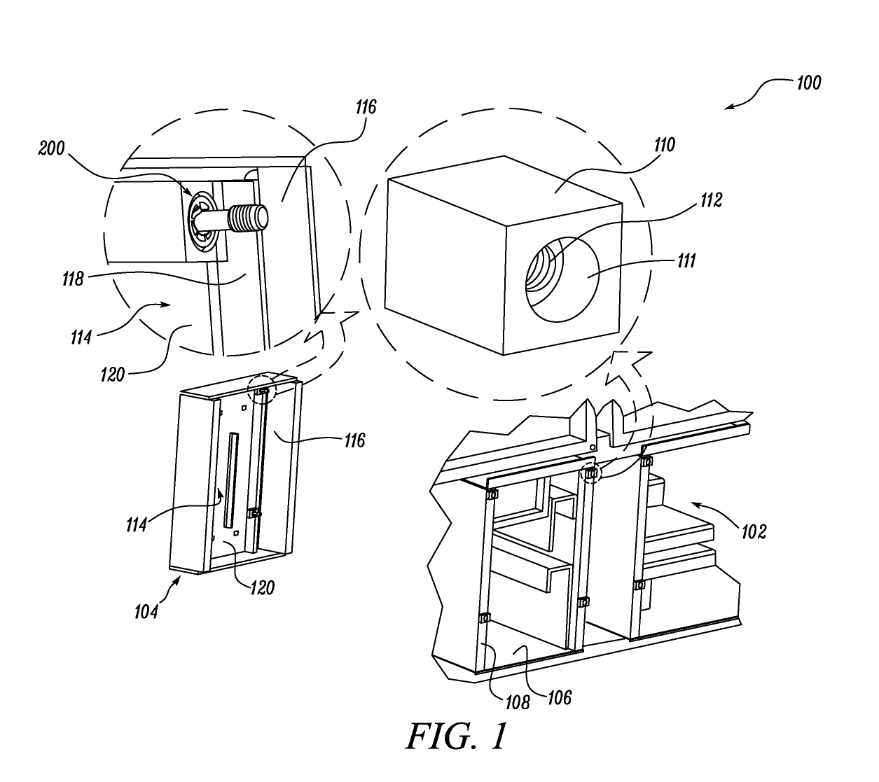

The present disclosure relates to a fastener assembly for a door of an enclosure. FIG. 1 illustrates an exemplary cabinet 100 having an enclosure 102 and a door assembly 104 for the enclosure 102. In an exemplary embodiment, the cabinet 100 is an inverter cabinet for an electric drive over haul truck. In various other embodiments, the cabinet 100 may be any cabinet used for various purposes such as a generator set cabinet, a wall/floor mounted cabinet or an independent cabinet used for any purposes.

The enclosure 102 of the cabinet 100 includes a housing 106 and a frame 108 defining an entrance to the housing 106 to facilitate access to the various components with the housing 106. The frame 108 may be an elevated frame disposed about a perimeter of the housing 106. In an aspect of the present disclosure, the door assembly 104 may be detachably coupled to the frame 108 to cover the entrance to the housing 106. The enclosure 102 may include a number of fastener receptacle blocks 110 which may be arranged about a perimeter of the frame 108. In an aspect of the present disclosure, the fastener receptacle block 110 may include a counter bore 111 and a threaded opening 112 extending beyond the counter bore 111 within the fastener receptacle block 110. An inner diameter of the threaded opening 112 may be lesser than an inner diameter of the counter bore 111. For example, the inner diameter of the counter bore 111 may be 1.5 times larger than the inner diameter of the threaded receptacle 112.

In an aspect of the present disclosure, the door assembly 104 may include a panel 114 and a flange 116 laterally extending about a perimeter of the panel 114. The flange 116 of the door assembly 104 may be configured to fit the door assembly 104 over the frame 108 to cover the entrance to the housing 106 of the enclosure 102. In an exemplary embodiment, the enclosure 102, and the door assembly 104 may all be made of a metal, such as steel, aluminum, etc. In alternate embodiments, the cabinet 100, the enclosure 102 and the door assembly 104 may be made of any other material such as composites, plastic etc.

Further, the door assembly 104 includes a seal 118 disposed on an inner surface 120 of the panel 114 and around the perimeter of the panel 114. As will be understood by a person having ordinary skill in the art, that the seal 118 may be a gasket configured to seal a junction between the frame 108 of the enclosure 102 and the panel 114 of the door assembly 104.

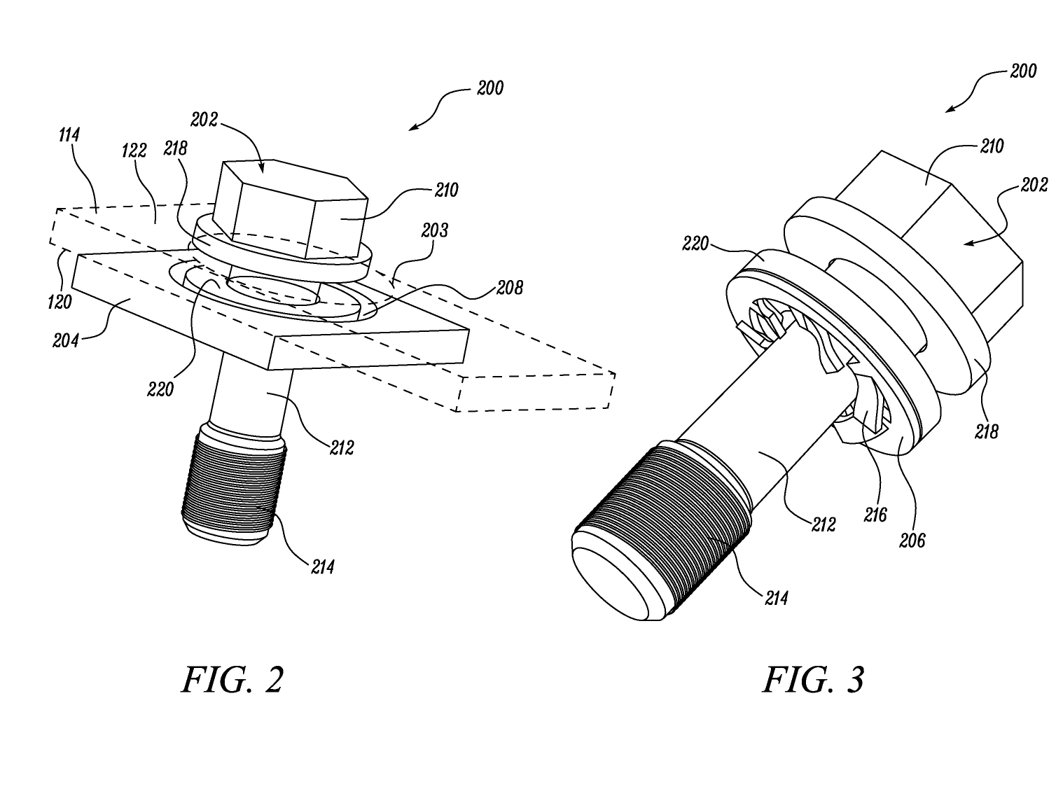

In an aspect of the present disclosure, the door assembly 104 may be further fastened to the frame 108 of the enclosure 102 by using a number of fastener assemblies 200. Each of the fastener assembly 200 may be arranged about a perimeter of the panel 114 of the door assembly 104. The fastener assembly 200 is further described in greater detail with reference to FIGS. 2 and 3.

FIGS. 2 and 3 illustrate two different views of the fastener assembly 200, according to an embodiment of the present disclosure. The fastener assembly 200 includes a fastener such as a bolt 202, a compression limiter 204, a retaining ring 206, and washer rings such as a first washer ring 218 and a second washer ring 220. The fastener assembly 200 may be configured to fasten the door assembly 104 to the frame 108.

The fastener assembly 200 is configured to be attached to the panel 114 extending from an outer surface 122 to the inner surface 120 of the panel 114. The panel 114 is configured to have a plurality of attachment points, at which, a fastener assembly 200 may be provided. The panel 114 includes a first circular opening 203 at the plurality of attachment points.

The compression limiter 204 is disposed on the inner surface 120 of the panel 114 and configured to press against the fastener receptacle block 110 on the frame 108 of the enclosure 102. In an aspect of the present disclosure, the compression limiter 204 is an unpainted rectangular pad and is made of a metal, such as aluminum, steel etc. In various other embodiments, the compression limiter 204 may be made of any other material such as the material of the door assembly 104, or plastic or any other composite material. The compression limiter 204 has a second circular opening 208. Furthermore, the compression limiter 204 is attached to the inner surface 120 of the panel 114 such that the second circular opening 208 of the compression limiter 204 aligns with the first circular opening 203 on the panel 114 of the door assembly 104. In an exemplary embodiment, the compression limiter 204 may be welded to the inner surface 120 of the panel 114.

Further, in the fastener assembly 200, the bolt 202 passes through the second circular opening 208 of the compression limiter 204. As shown in FIGS. 2 and 3, the bolt 202 includes a bolt head 210, a shank portion 212 and a threaded portion 214. In an aspect of the present disclosure, an outer diameter of the shank portion 212 is less than an outer diameter of the threaded portion 214. The threaded portion 214 of the bolt 202 is configured to be fastened to the threaded opening 112 of the fastener receptacle block 110. The counter bore 111 may be configured to facilitate the aligning of the bolt 202 as it enters into the fastener receptacle block 110.

Furthermore, the fastener assembly 200 includes the retaining ring 206 configured to be disposed within the second circular opening 208 of the compression limiter 204. An outer diameter of the retaining ring 206 is less than an inner diameter of the second circular opening 208, such that the retaining ring 206 fits within the second circular opening 208 of the compression limiter 204 without slipping out of the second circular opening 208.

In an aspect of the present disclosure, the retaining ring 206 further includes a number of tabs 216 protruding radially inwards and overlying the shank portion 212 of the bolt 202. The tabs 216 of the retaining ring 206 are configured to retain the bolt 202 with the door assembly 104. In an exemplary embodiment, the retaining ring 206 and the tabs 216 may be made of metal. Alternatively, the retaining ring 206 and the tabs 216 may be made up of plastic.

Furthermore, according to an aspect of the present disclosure, the fastener assembly 200 includes the first washer ring 218 and the second washer ring 220. The first washer ring 218 is configured to abut the bolt head 210 at one side and the outer surface 122 of the panel 114 at the second side. Further, the second washer ring 220 is configured to abut the retaining ring 206 at one side and the inner surface 120 of the panel 114 on the other side.

### INDUSTRIAL APPLICABILITY

Cabinets, such as inverter cabinets include doors that can be detached from an enclosure of the cabinet. The doors are generally fastened and/or sealed to a frame of the enclosure using fasteners and gasket seals. Fastening the doors to the enclosure may require a manual force to be applied on the door against the enclosure. However, applying too much force on the door may damage the fasteners and the seals. Also, when using such inverter cabinets in an electric drive machine, high electric shocks and high vibrations tend to bend and/or deform the doors and damage the fasteners. Additionally, while fastening and/or unfastening the door from the enclosure, the fasteners may tend to fall off from the door, which may not be desired.

In an aspect of the present disclosure, the flange 116 extending laterally around the perimeter of the panel 114 of the door assembly 104 prevents the door assembly 104 from bending and/or deforming during high strain vibrations, while maintaining durability of the seal 118. Furthermore, the flange 116 provided on the panel 114 prevents water ingression into the cabinet 100.

Further, the compression limiter 204 limits the amount of pressure or compression that can be applied while fastening the door assembly 104 to the enclosure 102. The compression limiter 204 is an unpainted metal pad which provides metal to metal contact with the fastener receptacle block 110 on the frame 108 of the enclosure 102 to limit the amount of compression that can be applied. Also, the unpainted metal surface of the compression limiter 204 provides earthing of the door assembly 104 to the enclosure 102 to prevent electrical shocks that may be harmful to an operator installing or uninstalling the cabinet 100. Furthermore, the compression limiter 204 of the fastener assembly 200 provides a cheap and compact solution for preventing the door assembly 104, the seal 118, and the fastener assembly 200 from being damaged.

Further, the retaining ring 206 is placed within and rotates freely within the second circular opening 208 of the compression limiter 204 which protects the retaining ring 206 from being damaged. Furthermore, the retaining ring 206 retains the bolt 202 with the door assembly 104, when the door assembly 104 is unfastened or detached from the enclosure 102. The tabs 216 of the retaining ring 206 provide retaining of the bolt 202 with the door assembly 104. For example, by virtue of the design of the tabs 216 being radially inward and the outside diameter of the threaded portion 214 being greater than the outside diameter of the shank portion 212, the bolt 202 may be pushed in through the compression limiter 204 and the retaining ring 206 but cannot be pulled out.

While aspects of the present disclosure have been particularly shown and described with reference to the embodiments above, it will be understood by those skilled in the art that various additional embodiments may be contemplated by the modification of the disclosed machines, systems and methods without departing from the spirit and scope of what is disclosed. Such embodiments should be understood to fall within the scope of the present disclosure as determined based upon the claims and any equivalents thereof.

What is claimed is:

1. A fastener assembly arranged about a perimeter of a door for an enclosure, the fastener assembly comprising:
a compression limiter disposed on an inner surface of the door and configured to press against a fastener receptacle block on the enclosure, the compression limiter having an opening;
a bolt passing through the opening of the compression limiter and configured to be fastened to a threaded opening in the fastener receptacle block; and
a retaining ring disposed in the opening of the compression limiter and configured to retain the bolt with the door.

2. The fastener assembly of claim 1, wherein the bolt includes a shank portion and a threaded portion, and wherein an outer diameter of the shank portion is less than an outer diameter of the threaded portion.

3. The fastener assembly of claim 2, wherein the retaining ring includes a plurality of tabs protruding radially inwards overlying the shank portion of the bolt.

4. The fastener assembly of claim 1, wherein the compression limiter is made of a metal having an unpainted metal surface, such that the unpainted metal surface provides earthing of the door to the enclosure.

5. The fastener assembly of claim 1 further comprises a first washer ring configured to abut a bolt head of the bolt and an outer surface of the door.

6. The fastener assembly of claim 1 further comprises a second washer ring configured to abut the retaining ring and the inner surface of the door.

7. A door for an enclosure comprising:
a panel configured to cover an entrance of the enclosure; and
a fastener assembly arranged about a perimeter of the panel, the fastener assembly including:
a compression limiter attached to an inner surface of the panel and configured to press against a fastener receptacle block on the enclosure, the compression limiter having an opening;
a bolt passing through the opening of the compression limiter and configured to be fastened to a threaded opening in the fastener receptacle block; and
a retaining ring disposed in the opening of the compression limiter and configured to retain the bolt with the panel.

8. The door of claim 7, wherein the bolt includes a shank portion and a threaded portion, and wherein an outer diameter of the shank portion is less than an outer diameter of the threaded portion.

9. The door of claim 8, wherein the retaining ring includes a plurality of tabs protruding radially inward overlying the shank portion of the bolt.

10. The door of claim 7, wherein the compression limiter is made of a metal having an unpainted metal surface, such that the unpainted metal surface provides earthing of the door to the enclosure.

11. The door of claim 7, wherein the fastener assembly further comprises a first washer ring configured to abut a bolt head of the bolt and an outer surface of the panel.

12. The door of claim 7, wherein the fastener assembly further comprises a second washer ring configured to abut the retaining ring and the inner surface of the panel.

13. The door of claim 7 further comprises a flange laterally extending from the perimeter of the panel.

14. The door of claim 7 further comprises a continuous seal disposed on the inner surface and around the perimeter of the panel.

15. An inverter cabinet comprising:
an enclosure including:
a housing;
an entrance to the housing; and
a fastener receptacle block arranged about a perimeter of the entrance, the fastener receptacle block having a threaded opening; and
a door for the enclosure, the door including:
a panel covering the entrance to the housing; and
a fastener assembly arranged about a perimeter of the panel, the fastener assembly including:
a compression limiter attached to an inner surface of the panel and pressing against the fastener receptacle block, the compression limiter having an opening;
a bolt passing through the opening of the compression limiter and fastened to the threaded opening; and
a retaining ring disposed in the opening of the compression limiter, the retaining ring configured to retain the bolt with the panel.

16. The inverter cabinet of claim 15, wherein the bolt includes a shank portion and a threaded portion, and wherein an outer diameter of the shank portion is less than an outer diameter of the threaded portion.

17. The inverter cabinet of claim 16, wherein the retaining ring includes a plurality of tabs protruding radially inward overlying the shank portion of the bolt.

18. The inverter cabinet of claim 15, wherein the compression limiter is made of a metal.

19. The inverter cabinet of claim 15, wherein the door further comprises a flange laterally extending from the perimeter of the panel.

20. The inverter cabinet of claim 15, wherein the door further comprises a continuous seal disposed on the inner surface and around the perimeter of the panel.
